(19) United States
(12) Patent Application Publication
(10) Pub. No.: US 2026/0360288 A1
(43) Pub. Date: Nov. 12, 2026

(54) SCANNING DRIVING CIRCUIT AND DISPLAY PANEL

(71) Applicant: Everdisplay Optronics (Shanghai) Co., Ltd., Shanghai (CN)

(72) Inventors: Ying-Hsiang TSENG, Shanghai (CN); Lina XIAO, Shanghai (CN); Qi WANG, Shanghai (CN); Jie LIU, Shanghai (CN)

(73) Assignee: Everdisplay Optronics (Shanghai) Co., Ltd., Shanghai (CN)

(21) Appl. No.: 19/124,956

(22) PCT Filed: Sep. 12, 2023
(86) PCT No.: PCT/CN2023/118220

§ 371 Date: Apr. 28, 2025

(30) Foreign Application Priority Data
Jul. 27, 2023 (CN) 202310936327.9

(51) Int. Cl. G09G 3/20; G11C 19/28

(52) U.S. Cl. CPC G09G 3/20; G11C 19/287; G09G 2310/0286; G09G 2310/08

(57) ABSTRACT

A scanning driving circuit (30) and a display panel (10). The scanning driving circuit (30) includes a plurality of stages of shift register units and a timing controller (20), wherein each stage of shift register unit includes 13 transistors and three capacitors, and the timing controller (20) includes two timing control signal lines.

### CROSS REFERENCE TO RELATED APPLICATION

The present application is a U.S. National Stage of International Application No. PCT/CN2023/118220, filed on Sep. 12, 2023, which claims the benefit of priority to Chinese Application No. 202310936327.9, filed on Jul. 27, 2023, both of which are incorporated by reference herein in their entireties for all purposes.

### TECHNICAL FIELD

The present disclosure relates to the field of display panels, and specifically, to a scanning drive circuit and a display panel.

### BACKGROUND

The display panel includes a pixel array and a scanning drive circuit and a light-emitting drive circuit for controlling the pixel array. The display panel adopts a row-by-row scanning display mode, wherein the scanning drive circuit is used to generate a scanning signal to turn on each row of pixels in sequence.

The scanning drive circuit includes a plurality of cascaded shift register units, wherein the circuit of each stage of the shift register unit is usually mainly composed of several transistors, and a scanning signal Gout is output at the output terminal by inputting a clock signal CKV and a start pulse signal IN into the circuit.

Chinese patent CN105989797A provides a scanning circuit, as shown in FIGS. 1 and 2, FIG. 1 shows a circuit diagram of a shift register unit of the prior art; FIG. 2 shows a waveform diagram of a shift register unit of the prior art when it is working. “H” represents a high-level signal, and “L” represents a low-level signal. The transistor T5 and the transistor T6 in this circuit will restrain each other. When the display panel is used for a long time, the threshold voltage vth of the transistor shifts, or the aspect ratio of the transistor changes caused by the manufacturing process error of the display panel, they may all cause output of the scanning circuit of the display panel to be abnormal. As shown in FIG. 2, Gout is an ideal output signal, and Abnormal Gout is an abnormal output signal, which causes the display panel to display an abnormal picture. In addition, the second node N2 in the circuit of the shift register unit has an electrical floating problem at certain moments during operation, which causes the display panel to display abnormally and reduces reliability.

It should be noted that the information disclosed in the above background section is only used to enhance understanding of the background of the present disclosure, and therefore may include information that does not constitute prior art known to those of ordinary skill in the art.

### SUMMARY

In view of this, the present disclosure provides a scanning drive circuit and a display panel.

One aspect of the present disclosure provides a scanning drive circuit, including a plurality of stages of shift register units, wherein the shift register unit includes:
a first transistor, having a first electrode connected to a signal input terminal, a second electrode connected to a second node, and a gate connected to a second timing control terminal;
a second transistor, having a second electrode connected to the second node, and a gate connected to a first node;
a third transistor, having a first electrode connected to a first power supply, a second electrode connected to a first electrode of the second transistor, and a gate connected to a first timing control terminal;
a fourth transistor, having a first electrode connected to a second power supply, a second electrode connected to a fourth node, and a gate connected to the second timing control terminal;
a fifth transistor, having a first electrode connected to the second timing control terminal, a second electrode connected to the first node, and a gate connected to the second node;
a sixth transistor, having a first electrode connected to the second node, a second electrode connected to a fifth node, and a gate connected to the second power supply;
a seventh transistor, having a first electrode connected to the first power supply, a second electrode connected to a signal output terminal, and a gate connected to the first node;
an eighth transistor, having a first electrode connected to the signal output terminal, a second electrode connected to the first timing control terminal, and a gate connected to the fifth node;
a ninth transistor, having a first electrode connected to the fourth node, a second electrode connected to the first node, and a gate connected to a third node;
a tenth transistor, having a first electrode connected to the first timing control terminal, a second electrode connected to the third node, and a gate connected to the signal input terminal;
an eleventh transistor, having a first electrode connected to the third node, a second electrode connected to the second power supply, and a gate connected to the first timing control terminal;
a twelfth transistor, having a first electrode connected to the first node, and a gate connected to the fourth node;
a thirteenth transistor, having a first electrode connected to a second electrode of the twelfth transistor, a second electrode connected to the second power supply, and a gate connected to the first timing control terminal;
a first capacitor, having a first electrode connected to the first power supply, and a second electrode connected to the first node;
a second capacitor, having a first electrode connected to the fifth node, and a second electrode connected to the signal output terminal; and
a third capacitor, having a first electrode connected to the fourth node, and a second electrode connected to the third node.

In some embodiments, the scanning drive circuit further includes: a timing controller, wherein the timing controller includes a first timing control signal line and a second timing control signal line.

In some embodiments, the first timing control signal line is configured to output a first timing control signal; and the second timing control signal line is configured to output a second timing control signal.

In some embodiments, the first timing control signal and the second timing control signal are square wave signals with an identical output frequency and a phase difference of 180°.

In some embodiments, the shift register unit is configured to perform delay processing on a signal received from the signal input terminal under control of the first timing control signal and the second timing control signal, and the processed signal is output by the signal output terminal.

In some embodiments, the shift register unit of a previous stage outputs a scanning signal to the shift register unit of a next stage, and the shift register unit of a last stage outputs a scanning signal.

In some embodiments, in an odd-stage shift register unit, the first timing control terminal is connected to the first timing control signal line, and the second timing control terminal is connected to the second timing control signal line.

In some embodiments, in an even-stage shift register unit, the first timing control terminal is connected to the second timing control signal line, and the second timing control terminal is connected to the first timing control signal line.

In some embodiments, the first transistor to the thirteenth transistor are all P-type MOS transistors.

Another aspect of the present disclosure also provides a display panel, including any of the above-mentioned scanning drive circuits.

It should be understood that the above general description and the following detailed description are exemplary and explanatory only, and do not limit the present disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Apparently, the drawings in the following description are only some embodiments of the present disclosure. For those of ordinary skill in the art, other drawings can be obtained based on these drawings without exerting creative efforts.

FIG. 1 shows a circuit diagram of a shift register unit in the prior art;

FIG. 2 shows a waveform diagram of a shift register unit in the prior art when it is working;

FIG. 3 shows a schematic diagram of a display panel in an embodiment of the present disclosure;

FIG. 4 shows a cascade schematic diagram of a scanning drive circuit in an embodiment of the present disclosure;

FIG. 5 shows a circuit diagram of a shift register unit in an embodiment of the present disclosure;

FIG. 6 shows a waveform diagram when the shift register unit shown in FIG. 5 is operating;

FIG. 7 shows a schematic diagram of the conduction state of the shift register unit in stage t1 in FIG. 6;

FIG. 8 shows a schematic diagram of the conduction state of the shift register unit in stage t2 in FIG. 6;

FIG. 9 shows a schematic diagram of the conduction state of the shift register unit in stage t3 in FIG. 6; and

FIG. 10 shows a schematic diagram of the conduction state of the shift register unit in stage t4 in FIG. 6.

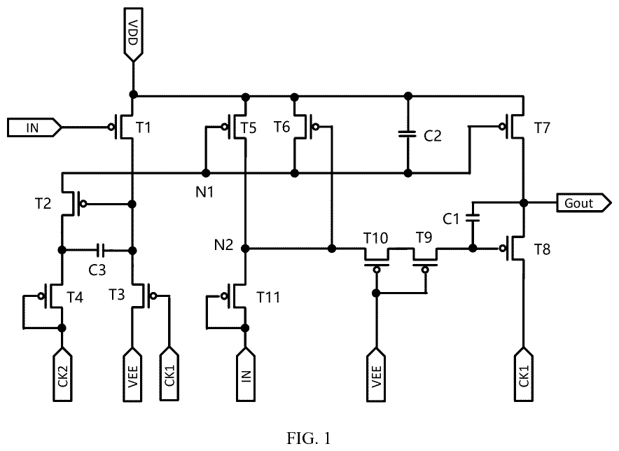

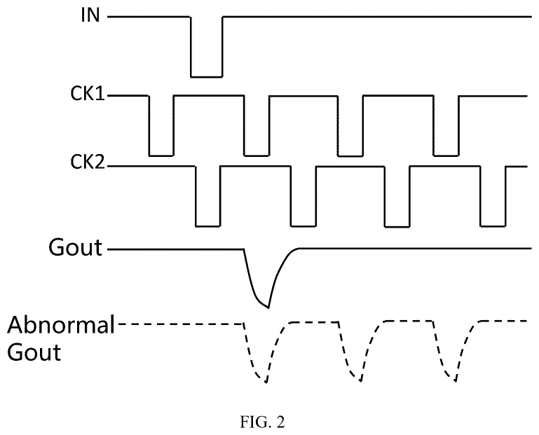

Reference numerals:

| | |
|---|---|
| 10 | display panel |
| 11 | display area |
| 20 | timing controller |
| 30 | scanning drive circuit |
| CKV1 | first timing control signal line |
| CKV2 | second timing control signal line |
| c1 | first timing control terminal |
| c2 | second timing control terminal |
| IN | signal input terminal |
| Gout | signal output terminal |
| T1 | first transistor |
| T2 | second transistor |
| T3 | third transistor |
| T4 | fourth transistor |
| T5 | fifth transistor |
| T6 | sixth transistor |
| T7 | seventh transistor |
| T8 | eighth transistor |
| T9 | ninth transistor |
| T10 | tenth transistor |
| T11 | eleventh transistor |
| T12 | twelfth transistor |
| T13 | thirteenth transistor |
| C1 | first capacitor |
| C2 | second capacitor |
| C3 | third capacitor |
| VDD | first power supply |
| VEE | second power supply |
| n1 | first node |
| n2 | second node |
| n3 | third node |
| n4 | fourth node |
| n5 | fifth node |

### DETAILED DESCRIPTION

Example embodiments will now be described more fully with reference to the accompanying drawings. Example embodiments may, however, be embodied in various forms and should not be construed as limited to the embodiments set forth herein. Rather, these embodiments are provided so that the present disclosure will be thorough and complete, and will fully convey the concept of example embodiments to those skilled in the art. The same reference numerals in the drawings represent the same or similar structures, and thus their repeated description will be omitted.

The use of “first”, “second” and similar words in specific descriptions does not imply any order, quantity or importance, but is only used to distinguish different components. In addition, in the description of the present disclosure, the orientation or positional relationship indicated by the terms “upper”, “lower”, etc. is based on the orientation or positional relationship shown in the drawings. It is only for convenience of description and does not indicate or imply that the devices or elements must have a specific orientation, and be constructed and operated in a specific orientation, and therefore are not to be construed as limitations of the present disclosure.

It should be noted that, as long as there is no conflict, embodiments of the present disclosure, and features in different embodiments can be combined with each other.

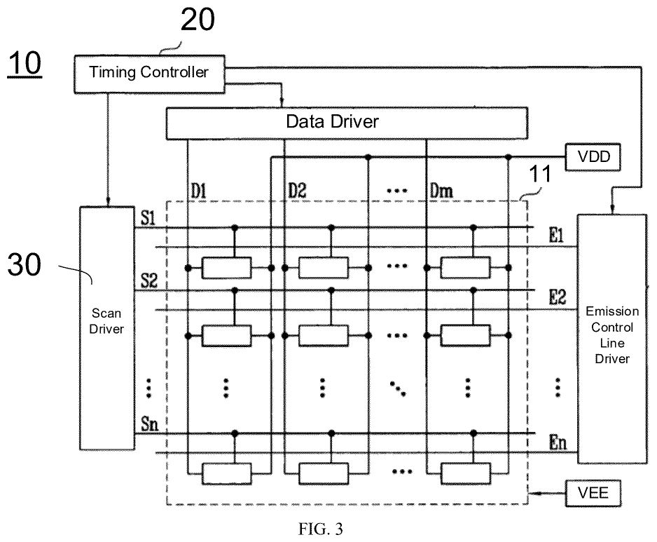

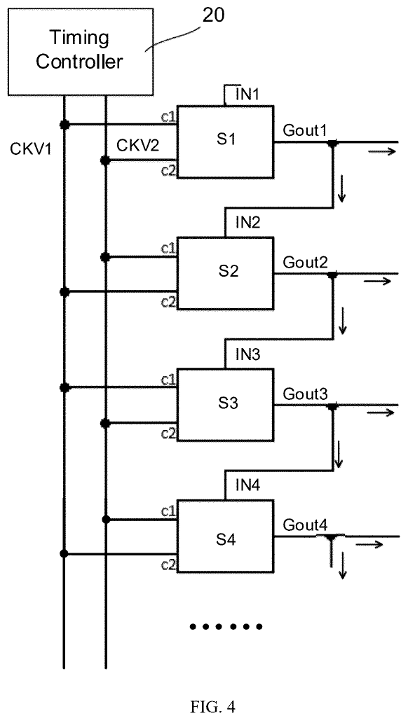

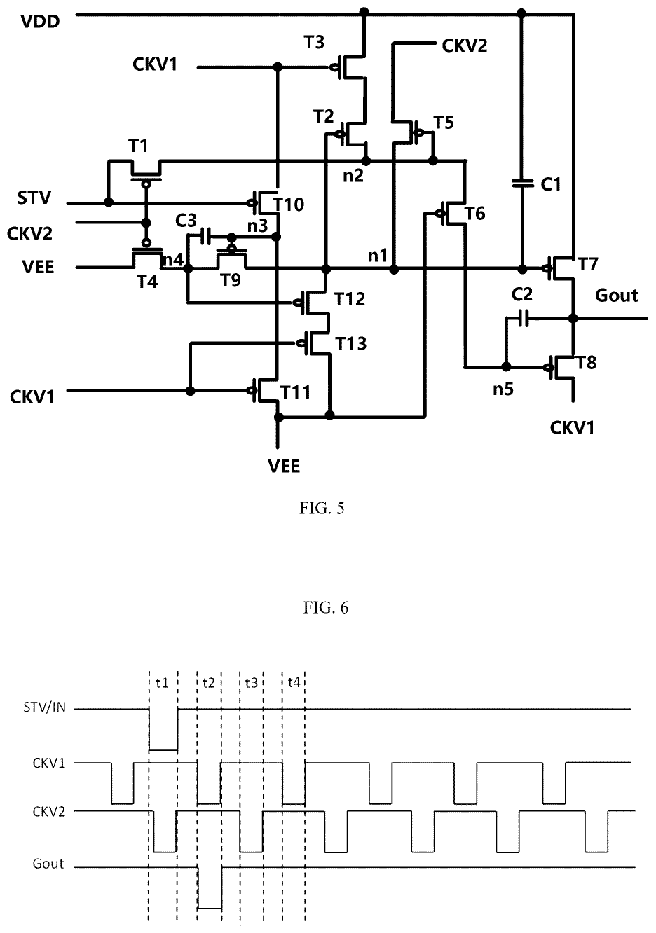

The inventor of this application provides a solution to the problems existing in the related art through detailed and in-depth research. As shown in FIGS. 3 to 5, FIG. 3 shows a schematic diagram of a display panel in an embodiment of the present disclosure; FIG. 4 shows a cascade schematic diagram of a scanning drive circuit in an embodiment of the present disclosure; FIG. 5 shows a circuit diagram of a shift register unit in an embodiment of the present disclosure. The embodiment of the present disclosure discloses a scanning drive circuit 30 and a display panel 10. The scanning drive circuit 30 includes a plurality of stages of shift register units and a timing controller 20, wherein each stage of the shift register unit includes 13 transistors, 3 capacitors, a signal input terminal IN, a signal output terminal Gout and three timing control terminals. The timing controller 20 includes three timing control signal lines. The scanning drive circuit and the display panel of the present disclosure solve the mutual restraint between transistors by providing a new 13T3C shift register unit, so that the scanning circuit is more stable, and the display abnormality caused by the fluctuation of the aspect ratio of the transistor due to the threshold voltage offset or the manufacturing process error is avoided, thereby improving the service life of the display panel; in addition, the shift register unit solves the problem of electrical floating of the nodes in the circuit, and improves the reliability of the display panel.

The specific implementation of the present disclosure is further described in detail below in conjunction with the accompanying drawings.

As shown in FIG. 3, the present disclosure provides a display panel 10, which includes a display area 11 and a non-display area. The scanning drive circuit 30, the data driver and the light-emitting drive circuit are located in the non-display area of the display panel 10. The display area 11 includes light-emitting pixels and pixel circuits arranged in an array. The light-emitting pixels emit light under the joint action of the scanning drive circuit 30, the data driver, the light-emitting drive circuit and the pixel circuit.

As shown in FIGS. 3 and 4, the present disclosure also provides a scanning drive circuit 30, which includes a plurality of stages of shift register units and a timing controller 20.

In some embodiments, the shift register unit includes 13 transistors, 3 capacitors, a signal input terminal IN, a signal output terminal Gout, a first timing control terminal c1, a second timing control terminal c2 and a third timing control terminal c3. Each stage of the shift register unit outputs a scan signal. The scan signal is input to a row of pixel circuits in the display area 11 of the display panel 10, to drive the row of pixels to emit light. The shift register unit of the previous stage simultaneously outputs the scan signal to the signal input terminal IN of the shift register unit of the next stage as a start signal. The shift register unit of the last stage outputs a scan signal that is only input to that row of the pixel circuit, because there is no next stage.

Specifically, in FIG. 4, four cascaded shift register units are shown as an example. The start pulse signal STV is input to the signal input terminal IN1 of the first-stage shift register unit S1 as the input signal. The signal output terminal Gout1 of the first-stage shift register unit S1 outputs the scan signal as the input signal of the second-stage shift register unit S2. The signal output terminal Gout1 of the first-stage shift register unit S1 is connected to the signal input terminal IN2 of the second-stage shift register unit S2. The signal output terminal Gout2 of the second-stage shift register unit S2 outputs the scan signal as the input signal of the third-stage shift register unit S3. The signal output terminal Gout2 of the second-stage shift register unit S2 is connected to the signal input terminal IN3 of the third-stage shift register unit S3. The signal output terminal Gout3 of the third-stage shift register unit S3 outputs the scan signal as the input signal of the fourth-stage shift register unit S4. The signal output terminal Gout3 of the third-stage shift register unit S3 is connected to the signal input terminal IN4 of the fourth-stage shift register unit S4. The shift register units of subsequent stages repeat this to form the scanning drive circuit 30.

In some embodiments, as shown in FIG. 4, the timing controller 20 includes a first timing control signal line CKV1 and a second timing control signal line CKV2. The first timing control signal line CKV1 is configured to output a first timing control signal. The second timing control signal line CKV2 is configured to output a second timing control signal. The first timing control signal and the second timing control signal are square wave signals with an identical output frequency and a phase difference of 180°.

In some preferred embodiments, continuing to refer to FIG. 4, further, the first timing control terminal c1 of the odd-stage shift register unit is connected to the first timing control signal line CKV1, for receiving the first timing control signal, and the second timing control terminal c2 thereof is connected to the second timing control signal line CKV2, for receiving the second timing control signal. The first timing control terminal c1 of the even-stage shift register unit is connected to the second timing control signal line CKV2, for receiving the second timing control signal, and the second timing control terminal c2 thereof is connected to the first timing control signal line CKV1, for receiving the first timing control signal.

In some embodiments, the shift register unit is configured to conduct delay processing on a signal received from the signal input terminal IN under control of the first timing control signal and the second timing control signal, and the processed signal is output by the signal output terminal Gout. The signal is output to the display area 11 as a scanning signal or input to the signal input terminal IN of the next stage shift register unit.

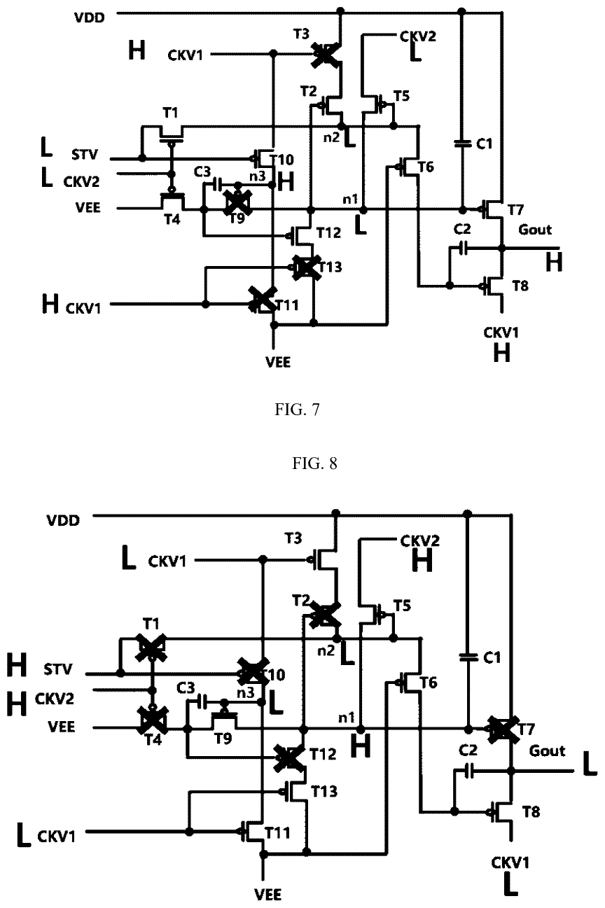

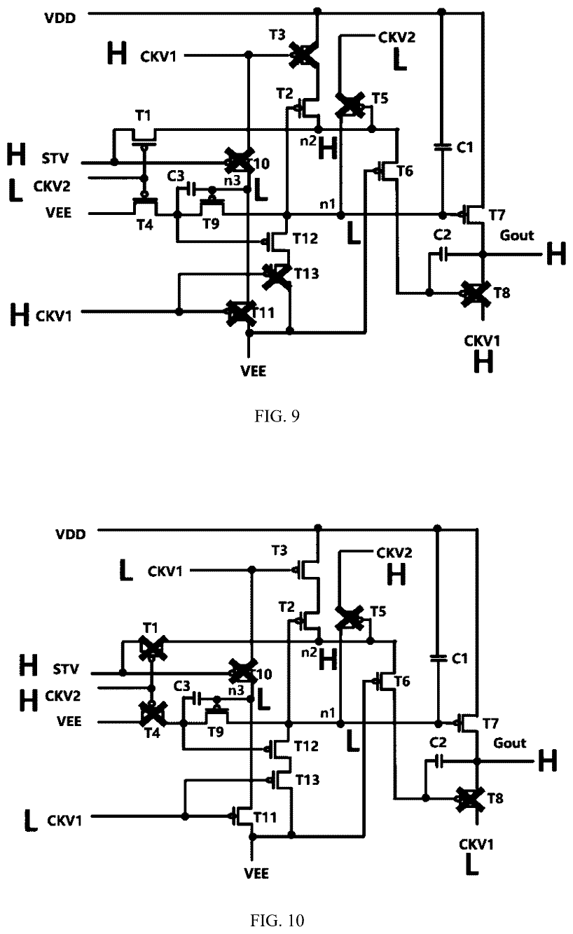

In some embodiments, referring to FIGS. 5 to 10, FIG. 6 shows a waveform diagram when the shift register unit shown in FIG. 5 is operating; FIG. 7 shows a schematic diagram of the conduction state of the shift register unit in stage t1 in FIG. 6; FIG. 8 shows a schematic diagram of the conduction state of the shift register unit in stage t2 in FIG. 6; FIG. 9 shows a schematic diagram of the conduction state of the shift register unit in stage t3 in FIG. 6; FIG. 10 shows a schematic diagram of the conduction state of the shift register unit in stage t4 in FIG. 6.

As shown in FIG. 5, the shift register unit of the embodiment of the present disclosure includes 13 transistors, 3 capacitors, a signal input terminal IN, a signal output terminal Gout, a first timing control terminal c1 and a second timing control terminal c2. The first electrode of the first transistor T1 is connected to the signal input terminal IN, the second electrode thereof is connected to the second node n2, and the gate thereof is connected to the second timing control terminal c2. The second electrode of the second transistor T2 is connected to the second node n2, and the gate thereof is connected to the first node n1. The first electrode of the third transistor T3 is connected to the first power supply VDD, the second electrode thereof is connected to the first electrode of the second transistor T2, and the gate thereof is connected to the first timing control terminal c1. The first electrode of the fourth transistor T4 is connected to the second power supply VEE, the second electrode thereof is connected to the fourth node n4, and the gate thereof is connected to the second timing control terminal c2. The first electrode of the fifth transistor T5 is connected to the second timing control terminal c2, the second electrode thereof is connected to the first node n1, and the gate thereof is connected to the second node n2. The first electrode of the sixth transistor T6 is connected to the second node n2, the second electrode thereof is connected to the fifth node n5, and the gate thereof is connected to the second power supply VEE. The first electrode of the seventh transistor T7 is connected to the first power supply VDD, the second electrode thereof is connected to the signal output terminal Gout, and the gate thereof is connected to the first node n1. The first electrode of the eighth transistor T8 is connected to the signal output terminal Gout, the second electrode thereof is connected to the first timing control terminal c1, and the gate thereof is connected to the fifth node n5. The first electrode of the ninth transistor T9 is connected to the fourth node n4, the second electrode thereof is connected to the first node n1, and the gate thereof is connected to the third node n3. The first electrode of the tenth transistor T10 is connected to the first timing control terminal c1, the second electrode thereof is connected to the third node n3, and the gate thereof is connected to the signal input terminal IN. The first electrode of the eleventh transistor T11 is connected to the third node n3, the second electrode thereof is connected to the second power supply VEE, and the gate thereof is connected to the first timing control terminal c1. The first electrode of the twelfth transistor T12 is connected to the first node n1, and the gate thereof is connected to the fourth node n4. The first electrode of the thirteenth transistor T13 is connected to the second electrode of the twelfth transistor T12, the second electrode thereof is connected to the second power supply VEE, and the gate thereof is connected to the first timing control terminal c1. The first electrode of the first capacitor C1 is connected to the first power supply VDD, and the second electrode thereof is connected to the first node n1. The first electrode of the second capacitor C2 is connected to the fifth node n5, and the second electrode thereof is connected to the signal output terminal Gout. The first electrode of the third capacitor C3 is connected to the fourth node n4, and the second electrode thereof is connected to the third node n3. The first power supply VDD provides a positive voltage signal, and the second power supply VEE provides a negative voltage signal.

In this embodiment, the first transistor T1 to the thirteenth transistor T13 are all P-type MOS transistors. The control terminal of the PMOS transistor is a gate, the first electrode of the PMOS transistor is a source electrode, and the second electrode of the PMOS transistor is a drain electrode, or the first electrode is a drain electrode and the second electrode is a source electrode. The turn-on level of the PMOS transistor is a low level, and the turn-off level of the PMOS transistor is a high level. In some other embodiments, those skilled in the art can easily conclude that the shift register unit provided by the present disclosure can be easily changed to all N-type MOS transistors. Alternatively, the shift register unit provided by the present disclosure can also be easily changed to a CMOS transistor or the like.

In this embodiment, referring to FIG. 6, the waveform diagram shown in FIG. 6 includes four processes: t1, t2, t3 and t4. During these four processes, the output signal of the signal output terminal Gout of the above-mentioned shift register unit completes a process from setting to resetting. It should be noted that, for convenience of understanding, the high-level signal is represented by “H”, and the low-level signal is represented by “L” in the drawings. The relationship between the input and output of the shift register unit in the above four processes is analyzed below based on the waveform diagram in FIG. 6 and the circuit diagram in FIG. 5.

In this embodiment, referring to FIGS. 6 and 7, during the t1 process, the signal input terminal IN inputs a low level, the first timing control signal line CKV1 inputs a high level, and the second timing control signal line CKV2 inputs a low level. At this time, the first transistor T1, the second transistor T2, the fourth transistor T4, the fifth transistor T5, the sixth transistor T6, the seventh transistor T7, the eighth transistor T8, the tenth transistor T10 and the twelfth transistor T12 are turned on, and the third transistor T3, the ninth transistor T9, the eleventh transistor T11 and the thirteenth transistor T13 are turned off. Specifically, due to the low level of the signal input terminal IN, the second timing control signal line CKV2 and the second power supply VEE, the first transistor T1, the fourth transistor T4, the sixth transistor T6 and the tenth transistor T10 are turned on, a low level is written to the second node n2 by the signal input terminal IN through the first transistor T1, the fifth transistor T5 is turned on, a low level is written to the first node n1 by the second timing control signal line CKV2 through the fifth transistor T5, the seventh transistor T7 is turned on, and the eighth transistor T8 is turned on through the sixth transistor T6. Finally, the signal output terminal Gout outputs a high potential of the first timing control signal line CKV1 and the first power supply VDD.

In this embodiment, referring to FIGS. 6 and 8, during the t2 process, the signal input terminal IN inputs a high level, the first timing control signal line CKV1 inputs a low level, and the second timing control signal line CKV2 inputs a high level. At this time, the third transistor T3, the fifth transistor T5, the sixth transistor T6, the eighth transistor T8, the ninth transistor T9, the eleventh transistor T11 and the thirteenth transistor T13 are turned on, and the first transistor T1, the second transistor T2, the fourth transistor T4, the seventh transistor T7, the tenth transistor T10 and the twelfth transistor T12 are turned off. Specifically, the eleventh transistor T11 is turned on by the low level of the first timing control signal line CKV1, the ninth transistor T9 is turned on through the eleventh transistor T11, the high level of the second timing control signal line CKV2 causes the first node n1 to be refreshed to a high level through the fifth transistor T5, the seventh transistor T7 is turned off, the second node n2 maintains the low potential of the previous moment, and the eighth transistor T8 is turned on. Finally, the signal output terminal Gout outputs the low potential of the second timing control signal line CKV2.

In this embodiment, referring to FIGS. 6 and 9, during the t3 process, the signal input terminal IN inputs a high level, the first timing control signal line CKV1 inputs a high level, and the second timing control signal line CKV2 inputs a low level. At this time, the first transistor T1, the second transistor T2, the fourth transistor T4, the sixth transistor T6, the seventh transistor T7, the ninth transistor T9 and the twelfth transistor T12 are turned on, and the third transistor T3, the fifth transistor T5, the eighth transistor T8, the tenth transistor T10, the eleventh transistor T11 and the thirteenth transistor T13 are turned off. Specifically, the first transistor T1 and the fourth transistor T4 are turned on by the second timing control signal line CKV2, the first node n1 is refreshed to a low level by the second power supply VEE through the ninth transistor T9 and the fourth transistor T4, the seventh transistor T7 is turned on, the second node n2 is refreshed to a high level by the signal input terminal IN through the first transistor T1, the fifth transistor T5 is turned off, and the eighth transistor T8 is also turned off through the sixth transistor T6. Finally, the signal output terminal Gout outputs a high potential of the first power supply VDD through the seventh transistor T7.

In this embodiment, referring to FIGS. 6 and 10, during process t4, the signal input terminal IN inputs a high level, the first timing control signal line CKV1 inputs a low level, and the second timing control signal line CKV2 inputs a high level. At this time, the second transistor T2, the third transistor T3, the sixth transistor T6, the seventh transistor T7, the ninth transistor T9, the eleventh transistor T11, the twelfth transistor T12, and the thirteenth transistor T13 are turned on, and the first transistor T1, the fourth transistor T4, the fifth transistor T5, the eighth transistor T8, and the tenth transistor T10 are turned off. Specifically, the third transistor T3, the eleventh transistor T11 and the thirteenth transistor T13 are turned on by the first timing control signal line CKV1, the first transistor T1 and the fourth transistor T4 are turned off by the second timing control signal line CKV2, the ninth transistor T9 and the twelfth transistor T12 maintain the turned-on state of the previous moment through the third capacitor C3, a low level is continuously written to the first node n1 by the second power supply VEE through the twelfth transistor T12 and the thirteenth transistor T13, the second transistor T2 and the seventh transistor T7 are turned on, a high potential is continuously written to the second node n2 by the first power supply VDD through the third transistor T3 and the second transistor T2, and the eighth transistor T8 is turned off. Finally, the final signal output terminal Gout outputs the high potential of the first power supply VDD through the seventh transistor T7.

The operation steps of the shift register unit after t4 repeat the t3 process to the t4 process until the next frame image begins to display, the start pulse signal STV or the signal input terminal IN inputs a low level, and re-enters the next round of the t1 process.

In this embodiment, the relationship between the input and output of the shift register unit is: if the start pulse signal STV or the signal input terminal IN is at a low level in a certain process, then under the action of the first timing control signal line CKV1 and the second timing control signal line CKV2, the signal output terminal Gout also outputs a low level in the next process. In other processes, the start pulse signal STV or the signal input terminal IN and the signal output terminal Gout all remain at a high level, until the start pulse signal STV or the signal input terminal IN inputs a low level again, and the signal output terminal Gout outputs a low level again. It is equivalent to that the shift register unit conducts delay processing on the low-level signal from the start pulse signal STV or the signal input terminal IN and then output it from the signal output terminal Gout.

In this embodiment, the 13T3C circuit of the shift register unit adds a thirteenth transistor T13 and changes some wiring settings, which solves the mutual restraint between the fifth transistor T5 and the sixth transistor T6, ensures the correctness of the output waveform, makes the scanning circuit more stable, avoids the display abnormality caused by the fluctuation of the aspect ratio of the transistor due to the threshold voltage offset or the manufacturing process error, improves the service life of the display panel; it also ensures the electrical floating problem of the second node n2, and improves the reliability of the display panel.

Based on the same inventive concept, an embodiment of the present disclosure also provides a display device, including the above-mentioned display panel 10 provided by the embodiment of the present disclosure. The display device can be: a mobile phone, a tablet computer, a television, a monitor, a notebook computer, a digital photo frame, a navigator, or any other product or component having a display function. For the implementation of the display device, reference may be made to the embodiment of the display panel 10 described above, and repeated details will not be described again.

The scanning drive circuit and the display panel of the present disclosure solve the mutual restraint between transistors by providing a new 13T3C shift register unit, so that the scanning circuit is more stable, and the display abnormality caused by the fluctuation of the aspect ratio of the transistor due to the threshold voltage offset or the manufacturing process error is avoided, thereby improving the service life of the display panel; in addition, the shift register unit solves the problem of electrical floating of the nodes in the circuit, and improves the reliability of the display panel.

The above content is a further detailed description of the present disclosure in combination with specific preferable embodiments, and it cannot be concluded that the specific implementation of the present disclosure is limited to these descriptions. For those of ordinary skill in the technical field to which the present disclosure belongs, several simple deductions or substitutions can be made without departing from the concept of the present disclosure, and all of them should be regarded as belonging to the protection scope of the present disclosure.

1. A scanning drive circuit, comprising a plurality of stages of shift register units, wherein the shift register unit comprises:
a first transistor, having a first electrode connected to a signal input terminal, a second electrode connected to a second node, and a gate connected to a second timing control terminal;
a second transistor, having a second electrode connected to the second node, and a gate connected to a first node;
a third transistor, having a first electrode connected to a first power supply, a second electrode connected to a first electrode of the second transistor, and a gate connected to a first timing control terminal;
a fourth transistor, having a first electrode connected to a second power supply, a second electrode connected to a fourth node, and a gate connected to the second timing control terminal;
a fifth transistor, having a first electrode connected to the second timing control terminal, a second electrode connected to the first node, and a gate connected to the second node;
a sixth transistor, having a first electrode connected to the second node, a second electrode connected to a fifth node, and a gate connected to the second power supply;
a seventh transistor, having a first electrode connected to the first power supply, a second electrode connected to a signal output terminal, and a gate connected to the first node;
an eighth transistor, having a first electrode connected to the signal output terminal, a second electrode connected to the first timing control terminal, and a gate connected to the fifth node;
a ninth transistor, having a first electrode connected to the fourth node, a second electrode connected to the first node, and a gate connected to a third node;
a tenth transistor, having a first electrode connected to the first timing control terminal, a second electrode connected to the third node, and a gate connected to the signal input terminal;
an eleventh transistor, having a first electrode connected to the third node, a second electrode connected to the second power supply, and a gate connected to the first timing control terminal;
a twelfth transistor, having a first electrode connected to the first node, and a gate connected to the fourth node;
a thirteenth transistor, having a first electrode connected to a second electrode of the twelfth transistor, a second electrode connected to the second power supply, and a gate connected to the first timing control terminal;
a first capacitor, having a first electrode connected to the first power supply, and a second electrode connected to the first node;
a second capacitor, having a first electrode connected to the fifth node, and a second electrode connected to the signal output terminal; and
a third capacitor, having a first electrode connected to the fourth node, and a second electrode connected to the third node.

2. The scanning drive circuit according to claim 1, further comprising: a timing controller, wherein the timing controller comprises a first timing control signal line and a second timing control signal line.

3. The scanning drive circuit according to claim 2, wherein the first timing control signal line is configured to output a first timing control signal; and the second timing control signal line is configured to output a second timing control signal.

4. The scanning drive circuit according to claim 3, wherein the first timing control signal and the second timing control signal are square wave signals with an identical output frequency and a phase difference of 180°.

5. The scanning drive circuit according to claim 3, wherein the shift register unit is configured to perform delay processing on a signal received from the signal input terminal under control of the first timing control signal and the second timing control signal, and the processed signal is output by the signal output terminal.

6. The scanning drive circuit according to claim 2, wherein the shift register unit of a previous stage outputs a scanning signal to the shift register unit of a next stage, and the shift register unit of a last stage outputs a scanning signal.

7. The scanning drive circuit according to claim 6, wherein in an odd-stage shift register unit, the first timing control terminal is connected to the first timing control signal line, and the second timing control terminal is connected to the second timing control signal line.

8. The scanning drive circuit according to claim 6, wherein in an even-stage shift register unit, the first timing control terminal is connected to the second timing control signal line, and the second timing control terminal is connected to the first timing control signal line.

9. The scanning drive circuit according to claim 1, wherein the first transistor to the thirteenth transistor are all P-type MOS transistors.

10. A display panel, comprising a scanning drive circuit, wherein the scanning drive circuit comprises a plurality of stages of shift register units, the shift register unit comprises:
a first transistor, having a first electrode connected to a signal input terminal, a second electrode connected to a second node, and a gate connected to a second timing control terminal;
a second transistor, having a second electrode connected to the second node, and a gate connected to a first node;
a third transistor, having a first electrode connected to a first power supply, a second electrode connected to a first electrode of the second transistor, and a gate connected to a first timing control terminal;
a fourth transistor, having a first electrode connected to a second power supply, a second electrode connected to a fourth node, and a gate connected to the second timing control terminal;
a fifth transistor, having a first electrode connected to the second timing control terminal, a second electrode connected to the first node, and a gate connected to the second node;
a sixth transistor, having a first electrode connected to the second node, a second electrode connected to a fifth node, and a gate connected to the second power supply;
a seventh transistor, having a first electrode connected to the first power supply, a second electrode connected to a signal output terminal, and a gate connected to the first node;
an eighth transistor, having a first electrode connected to the signal output terminal, a second electrode connected to the first timing control terminal, and a gate connected to the fifth node;
a ninth transistor, having a first electrode connected to the fourth node, a second electrode connected to the first node, and a gate connected to a third node;
a tenth transistor, having a first electrode connected to the first timing control terminal, a second electrode connected to the third node, and a gate connected to the signal input terminal;
an eleventh transistor, having a first electrode connected to the third node, a second electrode connected to the second power supply, and a gate connected to the first timing control terminal;
a twelfth transistor, having a first electrode connected to the first node, and a gate connected to the fourth node;
a thirteenth transistor, having a first electrode connected to a second electrode of the twelfth transistor, a second electrode connected to the second power supply, and a gate connected to the first timing control terminal;
a first capacitor, having a first electrode connected to the first power supply, and a second electrode connected to the first node;
a second capacitor, having a first electrode connected to the fifth node, and a second electrode connected to the signal output terminal; and
a third capacitor, having a first electrode connected to the fourth node, and a second electrode connected to the third node.

11. The display panel according to claim 10, wherein the scanning drive circuit further comprises: a timing controller, wherein the timing controller comprises a first timing control signal line and a second timing control signal line.

12. The display panel according to claim 11, wherein the first timing control signal line is configured to output a first timing control signal; and the second timing control signal line is configured to output a second timing control signal.

13. The display panel according to claim 12, wherein the first timing control signal and the second timing control signal are square wave signals with an identical output frequency and a phase difference of 180°.

14. The display panel according to claim 12, wherein the shift register unit is configured to perform delay processing on a signal received from the signal input terminal under control of the first timing control signal and the second timing control signal, and the processed signal is output by the signal output terminal.

15. The display panel according to claim 11, wherein the shift register unit of a previous stage outputs a scanning signal to the shift register unit of a next stage, and the shift register unit of a last stage outputs a scanning signal.

16. The display panel according to claim 15, wherein in an odd-stage shift register unit, the first timing control terminal is connected to the first timing control signal line, and the second timing control terminal is connected to the second timing control signal line.

17. The display panel according to claim 15, wherein in an even-stage shift register unit, the first timing control terminal is connected to the second timing control signal line, and the second timing control terminal is connected to the first timing control signal line.

18. The display panel according to claim 10, wherein the first transistor to the thirteenth transistor are all P-type MOS transistors.
